(19) United States
(12) Patent Application Publication
(10) Pub. No.: US 2025/0105790 A1
(43) Pub. Date: Mar. 27, 2025

(54) VOLTAGE RIPPLE CANCELLATION IN A TRANSMISSION CIRCUIT

(71) Applicant: Qorvo US, Inc., Greensboro, NC (US)

(72) Inventor: Nadim Khlat, Cugnaux (FR)

(21) Appl. No.: 18/832,084

(22) PCT Filed: Jan. 9, 2023
(86) PCT No.: PCT/US2023/060303

§ 371 Date: Jul. 22, 2024

Related U.S. Application Data
(60) Provisional application No. 63/303,530, filed on Jan. 27, 2022.
(60) Provisional application No. 63/329,991, filed on Apr. 12, 2022.

(51) Int. Cl. H03F 1/02; H03F 1/32; H03F 3/19; H03F 3/24

(52) U.S. Cl. CPC H03F 1/0227; H03F 1/32; H03F 3/19; H03F 3/245; H03F 2200/451

(57) ABSTRACT

Voltage ripple cancellation in a transmission circuit is provided. The transmission circuit includes a power amplifier circuit that amplifies a radio frequency (RF) signal based on a modulated voltage and a modulated current. Specifically, the modulated current is generated inside the power amplifier circuit based on a time-variant input power of the RF signal, and the modulated voltage is generated by an envelope tracking integrated circuit (ETIC) based on a time-variant target voltage and provided to the power amplifier circuit via a conductive path. Collectively, the ETIC and the conductive path present a total inductive impedance that interacts with the modulated current to cause a ripple in the modulated voltage at the power amplifier circuit. Herein, a transceiver circuit is configured to add a compensation term to the modulated target voltage to cancel the ripple in the modulated voltage to thereby improve overall RF performance of the transmission circuit.

### RELATED APPLICATIONS

This application claims the benefit of U.S. provisional patent application Ser. No. 63/303,530, filed on Jan. 27, 2022, and U.S. provisional patent application Ser. No. 63/329,991, filed on Apr. 12, 2022, the disclosures of which are hereby incorporated herein by reference in their entireties.

### FIELD OF THE DISCLOSURE

The technology of the disclosure relates generally to a transmission circuit that amplifies and transmits a radio frequency (RF) signal.

### BACKGROUND

Mobile communication devices have become increasingly common in current society for providing wireless communication services. The prevalence of these mobile communication devices is driven in part by the many functions that are now enabled on such devices. Increased processing capability in such devices means that mobile communication devices have evolved from being pure communication tools into sophisticated mobile multimedia centers that enable enhanced user experiences.

The redefined user experience relies on a higher data rate offered by advanced fifth generation (5G) and 5G new radio (5G-NR) technologies, which typically transmit and receive radio frequency (RF) signals in millimeter wave spectrums. Given that the RF signals are more susceptible to attenuation and interference in the millimeter wave spectrums, the RF signals are typically amplified by state-of-the-art power amplifiers to help boost the RF signals to higher power before transmission.

Envelope tracking (ET) is a power management technology designed to improve operating efficiency and/or linearity performance of the power amplifiers. In an ET power management circuit, a power management integrated circuit (PMIC) is configured to generate a time-variant ET voltage based on a time-variant voltage envelope of the RF signals, and the power amplifiers are configured to amplify the RF signals based on the time-variant ET voltage. Understandably, the better the time-variant ET voltage is aligned with the time-variant voltage envelope in time and amplitude, the better the performance (e.g., efficiency and/or linearity) that can be achieved at the power amplifiers. However, the time-variant ET voltage can become misaligned from the time-variant voltage envelope in time and/or amplitude due to a range of factors (e.g., group delay, impedance mismatch, etc.). As such, it is desirable to always maintain good alignment between the time-variant voltage and the time-variant voltage envelope and across a wide modulation bandwidth.

### SUMMARY

Embodiments of the disclosure relate to voltage ripple cancellation in a transmission circuit. The transmission circuit includes a power amplifier circuit configured to amplify a radio frequency (RF) signal based on a modulated voltage and a modulated current. Specifically, the modulated current is generated inside the power amplifier circuit based on a time-variant input power of the RF signal, and the modulated voltage is generated by an envelope tracking integrated circuit (ETIC) based on a time-variant target voltage and provided to the power amplifier circuit via a conductive path. Collectively, the ETIC and the conductive path present a total inductive impedance that can interact with the modulated current to cause a ripple in the modulated voltage at the power amplifier circuit. In embodiments disclosed herein, a transceiver circuit is configured to add a compensation term to the modulated target voltage to cancel the ripple in the modulated voltage to thereby improve overall RF performance of the transmission circuit.

In one aspect, a transmission circuit is provided. The transmission circuit includes a power amplifier circuit. The power amplifier circuit is configured to amplify an RF signal from a time-variant input power to a time-variant output power based on a modulated voltage. The transmission circuit also includes an ETIC. The ETIC is coupled to the power amplifier circuit via a conductive path and configured to generate the modulated voltage based on a modulated target voltage. The transmission circuit also includes a transceiver circuit. The transceiver circuit includes a signal processing circuit. The signal processing circuit is configured to generate the RF signal in the time-variant input power based on a time-variant modulation vector. The transceiver circuit also includes a voltage processing circuit. The voltage processing circuit is configured to generate a modulated digital target voltage from the time-variant modulation vector. The transceiver circuit also includes a current processing circuit. The current processing circuit is configured to add a compensation term to the modulated digital target voltage to thereby generate a modified digital target voltage. The transceiver circuit also includes a digital-to-analog converter (DAC). The DAC is configured to convert the modified digital target voltage into the modulated target voltage to thereby cancel a ripple in the modulated voltage.

In another aspect, a transceiver circuit is provided. The transceiver circuit includes a signal processing circuit. The signal processing circuit is configured to generate an RF signal in a time-variant input power based on a time-variant modulation vector. The transceiver circuit also includes a voltage processing circuit. The voltage processing circuit is configured to generate a modulated digital target voltage from the time-variant modulation vector. The transceiver circuit also includes a current processing circuit. The current processing circuit is configured to add a compensation term to the modulated digital target voltage to thereby generate a modified digital target voltage. The transceiver circuit includes a DAC. The DAC is configured to convert the modified digital target voltage into a modulated target voltage.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary existing transmission circuit, wherein an unwanted voltage distortion filter and a total inductive impedance presented to a power amplifier circuit can cause a memory distortion in the power amplifier circuit when the power amplifier circuit is coupled to a radio frequency (RF) front-end circuit;

FIG. 1B is a schematic diagram providing an exemplary illustration of an output stage of the power amplifier circuit in FIG. 1A;

FIG. 2 is a schematic diagram of an exemplary transmission circuit that can be configured according to various embodiments of the present disclosure to cancel the memory distortion in the existing transmission circuit of FIG. 1A;

FIG. 3 is a schematic diagram providing an exemplary illustration of a transceiver circuit in the transmission circuit of FIG. 2, which is configured according to one embodiment of the present disclosure;

FIG. 4 is a schematic diagram providing an exemplary illustration of a transceiver circuit in the transmission circuit of FIG. 2, which is configured according to another embodiment of the present disclosure; and

FIG. 5 is a schematic diagram of an exemplary user element wherein the transmission circuit of FIG. 2 can be provided to enable voltage ripple cancellation in the transmission circuit of FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to voltage ripple cancellation in a transmission circuit. The transmission circuit includes a power amplifier circuit configured to amplify a radio frequency (RF) signal based on a modulated voltage and a modulated current. Specifically, the modulated current is generated inside the power amplifier circuit based on a time-variant input power of the RF signal, and the modulated voltage is generated by an envelope tracking integrated circuit (ETIC) based on a time-variant target voltage and provided to the power amplifier circuit via a conductive path. Collectively, the ETIC and the conductive path present a total inductive impedance that can interact with the modulated current to cause a ripple in the modulated voltage at the power amplifier circuit. In embodiments disclosed herein, a transceiver circuit is configured to add a compensation term to the modulated target voltage to cancel the ripple in the modulated voltage to thereby improve overall RF performance of the transmission circuit.

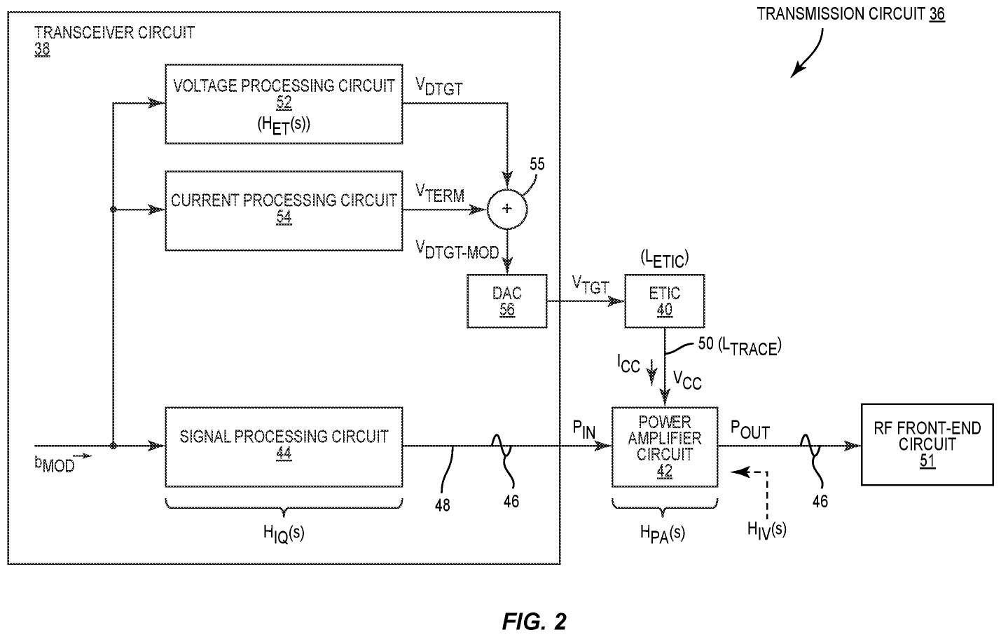

Before discussing the transmission circuit according to the present disclosure, starting at FIG. 2, a brief discussion of an existing transmission circuit is first provided to help understand how an unwanted voltage distortion filter and a total inductive impedance may become memory effect contributors that can degrade overall RF performance of the existing transmission circuit. Herein, a “memory effect” refers to a phenomenon that causes an electrical circuit (e.g., a power amplifier circuit) to generate an output signal that depends not only on a present input signal, but also on a past input signal(s). Accordingly, a degradation to the output signal caused by the memory effect is referred to as a “memory distortion” hereinafter.

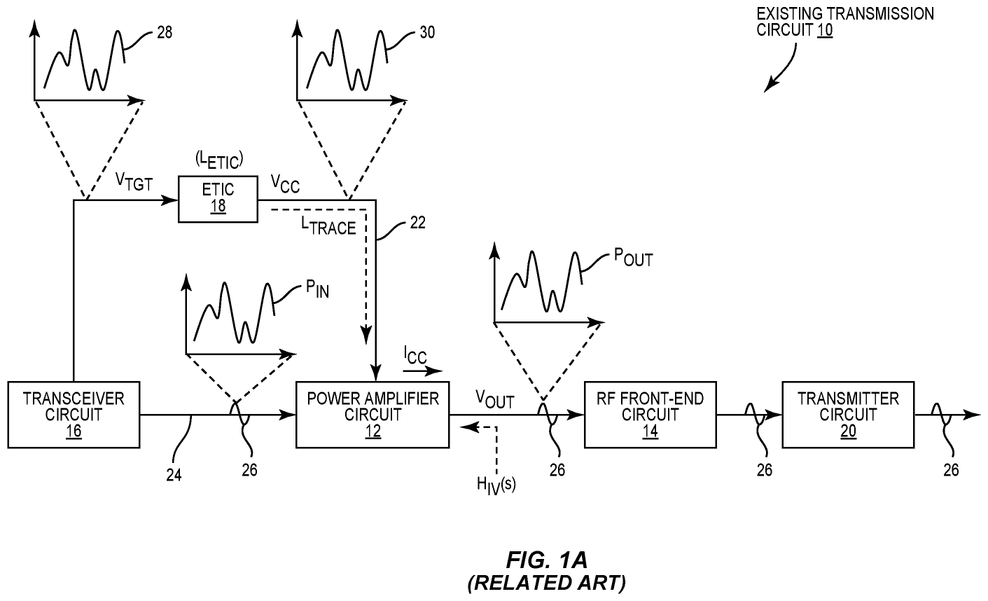

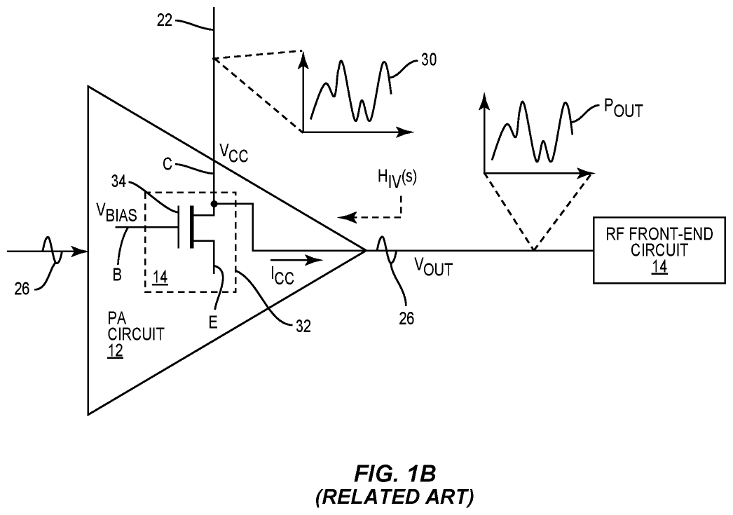

FIG. 1A is a schematic diagram of an exemplary existing transmission circuit 10, wherein an unwanted voltage distortion filter H_{IV}(s) and a total inductive impedance (L_{ETIC}+L_{TRACE}) presented to a power amplifier circuit 12 can cause a memory distortion in the power amplifier circuit 12 when the power amplifier circuit 12 is coupled to an RF front-end circuit 14. Notably, in the unwanted voltage distortion filter H_{IV}(s), “s” is a notation of Laplace transform.

The existing transmission circuit 10 includes a transceiver circuit 16, an ETIC 18, and a transmitter circuit 20, which can include an antenna(s) (not shown) as an example. The ETIC 18 is coupled to the power amplifier circuit 12 via a conductive voltage path 22 and the transceiver circuit 16 is coupled to the power amplifier circuit 12 via a conductive signal path 24. The ETIC 18 can be associated with an inductive ETIC impedance L_{ETIC} and the conductive voltage path 22 can be associated with an inductive trace impedance L_{TRACE}. As such, the ETIC 18 and the conductive voltage path 22 can collectively present the total inductive impedance (L_{ETIC}+L_{TRACE}) to the power amplifier circuit 12.

The transceiver circuit 16 is configured to generate an RF signal 26 having a time-variant input power P_{IN} and provides the RF signal 26 to the power amplifier circuit 12 via the conductive signal path 24. The transceiver circuit 16 is also configured to generate a time-variant target voltage V_{TGT}, which is associated with a time-variant target voltage envelope 28 that tracks the time-variant input power P_{IN} of the RF signal 26. The ETIC 18 is configured to generate a modulated voltage V_{CC} having a time-variant modulated voltage envelope 30 that tracks the time-variant target voltage envelope 28 of the time-variant target voltage V_{TGT} and provides the modulated voltage V_{CC} to the power amplifier circuit 12 via the conductive voltage path 22.

The power amplifier circuit 12, on the other hand, generates a modulated current I_{CC} as a function of the time-variant input power P_{IN}. Accordingly, the power amplifier circuit 12 can amplify the RF signal 26 to a time-variant output power P_{OUT} as a function of a time-variant output voltage V_{OUT} and the modulated current I_{CC} (e.g., P_{OUT}=V_{OUT}*I_{CC}). The power amplifier circuit 12 then provides the amplified RF signal 26 to the RF front-end circuit 14. The RF front-end circuit 14 may be a filter circuit that performs further frequency filtering on the amplified RF signal 26 before providing the amplified RF signal 26 to the transmitter circuit 20 for transmission.

FIG. 1B is a schematic diagram providing an exemplary illustration of an output stage 32 of the power amplifier circuit 12 in FIG. 1A. Common elements between FIGS. 1A and 1B are shown therein with common element numbers and will not be re-described herein.

The output stage 32 can include at least one transistor 34, such as a bipolar junction transistor (BJT) or a complementary metal-oxide semiconductor (CMOS) transistor. Taking the BJT as an example, the transistor 34 can include a base electrode B, a collector electrode C, and an emitter electrode E. The base electrode B is configured to receive a bias voltage VBIAS and the collector electrode C is coupled to the conductive voltage path 22 to receive the modulated voltage V_{CC}. The collector electrode C is also coupled to the RF front-end circuit 14 and configured to output the amplified RF signal 26 at the time-variant output voltage V_{OUT}. In this regard, the time-variant output voltage V_{OUT} can be a function of the modulated voltage V_{CC}. Accordingly, the time-variant output power P_{OUT} also becomes a function of the modulated voltage V_{CC} and the modulated current I_{CC}. Understandably, the power amplifier circuit 12 will operate with good efficiency and linearity when the time-variant modulated voltage V_{CC} and the modulated current I_{CC} are both aligned with the time-variant input power P_{IN}.

With reference back to FIG. 1A, the voltage distortion filter H_{IV}(s) and the total inductive impedance (L_{ETIC}+L_{TRACE}) are both memory effect contributors that can cause degraded RF performance in the existing transmission circuit 10. On one hand, the voltage distortion filter H_{IV}(s) is created when the power amplifier circuit 12 is coupled to the RF front-end circuit 14. As described in U.S. patent application Ser. No. 17/700,685, entitled “WIDEBAND TRANSMISSION CIRCUIT” (hereinafter “Application 685”), the voltage distortion filter H_{IV}(s) can alter the time-variant output voltage V_{OUT} across an entire modulation bandwidth of the RF signal 26. As a result, the time-variant output voltage V_{OUT} may become misaligned from the modulated voltage V_{CC} across the modulation bandwidth of the RF signal 26, thus causing unwanted memory distortion in the RF signal 26.

On the other hand, the total inductive impedance (L_{ETIC}+L_{TRACE}) can interact with the modulated current I_{CC} to create a ripple in the modulated voltage V_{CC} at the collector electrode C of the transistor 34. In this regard, it is desirable to suppress the unwanted voltage distortion filter H_{IV}(s) and the ripple in the modulated voltage V_{CC} to help improve RF performance of the existing transmission circuit 10.

In this regard, FIG. 2 is a schematic diagram of an exemplary transmission circuit 36 that can be configured according to various embodiments of the present disclosure to suppress the unwanted voltage distortion filter H_{IV}(s) and cancel the ripple in the modulated voltage V_{CC}. The transmission circuit 36 includes a transceiver circuit 38, an ETIC 40, and a power amplifier circuit 42. The transceiver circuit 38 includes a signal processing circuit 44 that generates an RF signal 46 from a time-variant modulation vector b_{MOD}^{→} and provides the RF signal 46 to the power amplifier circuit 42 via a conductive signal path 48.

The ETIC 40, which may be functionally equivalent to the ETIC 18 in FIG. 1A, is configured to generate a modulated voltage V_{CC} based on a modulated target voltage V_{TGT} and provides the modulated voltage V_{CC} to the power amplifier circuit 42 via a conductive path 50 (e.g., a conductive trace). Like the ETIC 18 and the conductive voltage path 22 in FIG. 1A, the ETIC 40 is associated with an inherent inductive impedance L_{ETIC} and the conductive path 50 is associated with an inductive trace impedance L_{TRACE}. As a result, the ETIC 40 and the conductive path 50 can collectively present a total inductive impedance (L_{ETIC}+L_{TRACE}) to the power amplifier circuit 42.

The power amplifier circuit 42 may be functionally equivalent to the power amplifier circuit 12 in FIG. 1A. As such, the power amplifier circuit 42 also includes the output stage 32, as previously illustrated in FIG. 1B, and is configured to amplify an RF signal 46 from a time-variant input power P_{IN} to a time-variant output power P_{OUT} based on the modulated voltage V_{CC} and a modulated current I_{CC}, which is generated inside the power amplifier circuit 42 as a function of the time-variant input power P_{IN}.

Like in the existing transmission circuit 10 of FIG. 1A, the modulated current I_{CC} can also interact with the total inductive impedance (L_{ETIC}+L_{TRACE}) to cause a ripple in the modulated voltage V_{CC}. In addition, as the power amplifier circuit 42 is also coupled to an RF front-end circuit 51, the unwanted voltage distortion filter H_{IV}(s) is also present at the power amplifier circuit 42. In this regard, it is necessary to cancel the ripple in the modulated voltage V_{CC} and suppress the unwanted voltage distortion filter H_{IV}(s) to help improve overall RF performance of the transmission circuit 36.

As discussed below, the transmission circuit 36 can be configured according to various embodiments of the present disclosure to cancel the ripple in the modulated voltage V_{CC} and/or suppress the unwanted voltage distortion filter H_{IV}(s). More specifically, the transmission circuit 36 can be configured to cancel the ripple in the modulated voltage V_{CC} either concurrent to or independent from suppression of the unwanted voltage distortion filter H_{IV}(s).

In an embodiment, the transceiver circuit 38 includes a voltage processing circuit 52. The voltage processing circuit 52 is configured to apply a complex voltage filter H_{ET}(s) to the time-variant modulation vector b_{MOD}^{→} and generate a modulated digital target voltage V_{DTGT} thereafter. The complex voltage filter H_{ET}(s), which can be expressed in equation (Eq. 1) below, is determined to compensate for the voltage distortion filter H_{IV}(s) presented to the power amplifier circuit 42 by coupling the power amplifier circuit 42 to the RF front-end circuit 51.

$${H}_{ET} ( s ) = {H}_{IQ} ( s ) * {H}_{PA} ( s ) * {H}_{IV} ( s ) \qquad ( Eq . 1 )$$

In the equation (Eq. 1), H_{IQ}(s) represents a transfer function of the signal processing circuit 44, and H_{PA}(s) represents a voltage gain transfer function of the power amplifier circuit 42. In this regard, H_{ET}(s) is a combined complex filter configured to match a combined filter that includes the transfer function H_{IQ}(s), the voltage gain transfer function H_{PA}(s), and the voltage distortion filter H_{IV}(s). For a more detailed description as to how the voltage distortion filter H_{IV}(s) was created and how the complex voltage filter H_{ET}(s) can effectively suppress the voltage distortion filter H_{IV}(s), please refer to the Application 685.

To cancel the ripple in the modulated voltage V_{CC}, the transceiver circuit 38 is further configured to include a current processing circuit 54. The current processing circuit 54 is configured to determine a compensation term V_{TERM} based on the modulated voltage V_{CC} and the total inductive impedance (L_{ETIC}+L_{TRACE}). Accordingly, a combiner 55 adds the compensation term V_{TERM} to the modulated digital target voltage V_{DTGT} to create a modified digital target voltage V_{DTGT-MOD}.

The transceiver circuit 38 also includes a digital-to-analog converter (DAC) 56. The DAC 56 is configured to convert the modified digital target voltage V_{DTGT-MOD} into the modulated target voltage V_{TGT} and provides the modulated target voltage V_{TGT} to the ETIC 40. By adding the compensation term V_{TERM} into the modulated target voltage V_{TGT}, it is possible to cancel the ripple in the modulated voltage V_{CC} received by the power amplifier circuit 42.

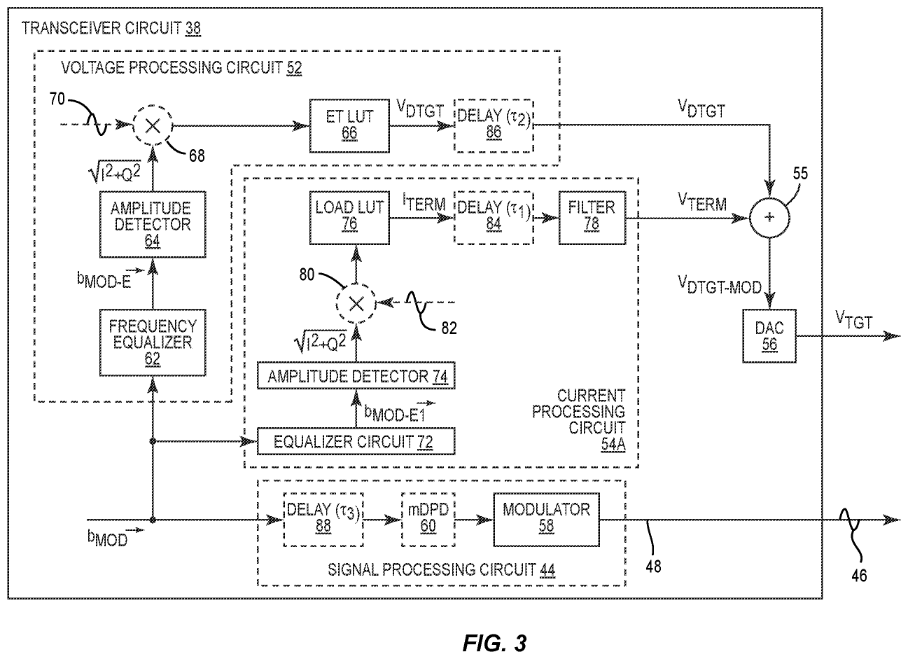

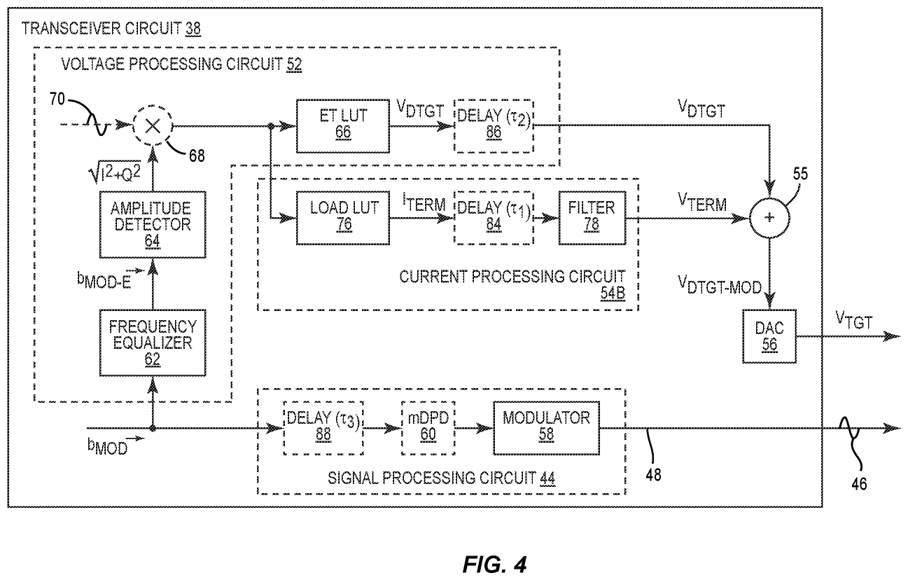

Specific embodiments of the transceiver circuit 38 are discussed below with reference to FIGS. 3 and 4. Common elements between FIGS. 2, 3, and 4 are shown therein with common element numbers and will not be re-described herein.

FIG. 3 is a schematic diagram providing an exemplary illustration of the transceiver circuit 38 configured according to one embodiment of the present disclosure. Herein, the signal processing circuit 44 is configured to generate the RF signal 46 from the time-variant modulation vector b_{MOD}^{→}. The time-variant modulation vector b_{MOD}^{→} may be generated by a digital baseband circuit (not shown) in the transceiver circuit 38 and includes both in-phase (I) and quadrature (Q) components. Since the time-variant modulation vector b_{MOD}^{→} is generated in a digital domain, the I and Q components can thus represent time-variant amplitudes of the time-variant modulation vector b_{MOD}^{→}.

The signal processing circuit 44 includes a modulator circuit 58, which is configured to generate the RF signal 46 in an analog domain based on the time-variant modulation vector b_{MOD}^{→} and modulate the RF signal 46 onto a selected frequency that falls within a modulation bandwidth of the transmission circuit 36. Understandably, since the modulator circuit 58 generates the RF signal 46 from the time-variant modulation vector b_{MOD}^{→}, the RF signal 46 will be associated with the time-variant input power P_{IN} that tracks the time-variant amplitudes of the time-variant modulation vector b_{MOD}^{→}. Accordingly, the I and Q components can also provide a digital representation of the time-variant input power P_{IN} of the RF signal 46.

The signal processing circuit 44 may further include a memory digital predistortion (mDPD) circuit 60. The mDPD circuit 60 can be configured to digitally pre-distort the time-variant modulation vector b_{MOD}^{→} before the modulator circuit 58 generates the RF signal 46.

The voltage processing circuit 52 includes a frequency equalizer circuit 62, an amplitude detector 64, and an ET lookup table (LUT) circuit 66. The frequency equalizer circuit 62 is configured to apply the complex voltage filter H_{ET}(s) to the time-variant modulation vector b_{MOD}^{→} to generate a frequency-equalized modulation vector b_{MOD-E}^{→}. Notably, the mDPD circuit 60 may also be configured to digitally pre-distort the time-variant modulation vector b_{MOD}^{→} before the time-variant modulation vector b_{MOD}^{→} is provided to the frequency equalizer circuit 62. In this regard, the frequency equalizer circuit 62 will apply the complex voltage filter H_{ET}(s) to the predistorted time-variant modulation vector b_{MOD}^{→} to generate a frequency-equalized modulation vector b_{MOD-E}^{→}. The amplitude detector 64 is configured to detect a time-variant amplitude \sqrt{I²+Q²} from the frequency-equalized modulation vector b_{MOD-E}^{→}. The ET LUT circuit 66 is configured to generate the modulated digital target voltage V_{DTGT} based on the detected time-variant amplitude \sqrt{I²+Q²}. The voltage processing circuit 52 may include a first scaler 68 to scale the detected time-variant amplitude \sqrt{I²+Q²} based on a first scaling factor 70 before the ET LUT circuit 66 generates the modulated digital target voltage V_{DTGT} from the detected time-variant amplitude \sqrt{I²+Q²}.

Herein, the transceiver circuit 38 includes a current processing circuit 54A, which is functionally equivalent to the current processing circuit 54 in FIG. 2. In an embodiment, the current processing circuit 54A includes an equalizer circuit 72, an amplitude detector circuit 74, a load LUT circuit 76, and a filter circuit 78. The equalizer circuit 72 is configured to apply a complex current filter H_{ETRC}(s) to the time-variant modulation vector b_{MOD}^{→} to generate an equalized modulation vector b_{MOD-E1}^{→}. Herein, the complex current filter H_{ETRC}(s) may be determined to provide a different shape in frequency response within the modulation bandwidth of the transmission circuit 36. In this regard, the complex current filter H_{ETRC}(s) can be different from the complex voltage filter H_{ET}(s).

The amplitude detector circuit 74 is configured to detect a time-variant amplitude \sqrt{I²+Q²} of the equalized modulation vector b_{MOD-E1}^{→}. The load LUT circuit 76 may include a current LUT (not shown) that is predetermined to correlate the time-variant input power P_{IN} (as represented by the detected time-variant amplitude \sqrt{I²+Q²} of the equalized modulation vector b_{MOD-E1}^{→}) with different digital current terms. Accordingly, the load LUT circuit 76 can generate a time-variant digital current term I_{TERM} based on the detected time-variant amplitude \sqrt{I²+Q²} of the equalized modulation vector b_{MOD-E1}^{→}. The current processing circuit 54A may include a second scaler 80 to scale the detected time-variant amplitude \sqrt{I²+Q²}based on a second scaling factor 82 before the load LUT circuit 76 generates the time-variant digital current term I_{TERM} from the detected time-variant amplitude \sqrt{I²+Q²}.

The filter circuit 78 is configured to convert the time-variant digital current term I_{TERM} into the compensation term V_{TERM}. In a non-limiting example, the filter circuit 78 can be configured to convert the time-variant digital current term I_{TERM} into the compensation term V_{TERM} based on a Z-transform function expressed in equation (Eq. 2).

$${V}_{TERM} = [ ( {L}_{ETIC} + {L}_{TRACE} ) / {T}_{S} ] * ( 1 - {z}^{- ⌉} ) \qquad ( Eq . 2 )$$

In the equation (Eq. 2), T_{S} represents a sampling clock period used in the digital domain, and z⁻¹ represents the Z transform. The combiner 55 is configured to combine the compensation term V_{TERM} with the modulated digital target voltage V_{DTGT} to create the modified digital target voltage V_{DTGT-MOD}.

In an embodiment, the current processing circuit 54A may include an adjustable delay circuit 84. The adjustable delay circuit 84 may be coupled between the load LUT circuit 76 and the filter circuit 78. The adjustable delay circuit 84 may be configured to introduce an adjustable delay term τ₁ into the time-variant digital current term I_{TERM}. The adjustable delay term τ₁ may be determined (e.g., via experiment) to cause the modulated current I_{CC} to be time aligned with the modulated voltage V_{CC} at the power amplifier circuit 42.

In addition, the voltage processing circuit 52 may include a second delay circuit 86 and the signal processing circuit 44 may include a third delay circuit 88. The second delay circuit 86 may be configured to introduce a second adjustable delay term τ₂ into the modulated digital target voltage V_{DTGT}. The third delay circuit 88 may be configured to introduce a third adjustable delay term τ₃ into the time-variant modulation vector b_{MOD}. In this regard, the adjustable delay term τ₁, the second adjustable delay term τ₂, and/or the third adjustable delay term τ₃ may be adjusted to ensure proper alignment among the modulated voltage V_{CC}, the modulated current I_{CC}, and the time-variant input power P_{IN} at the power amplifier circuit 42.

FIG. 4 is a schematic diagram providing an exemplary illustration of the transceiver circuit 38 configured according to another embodiment of the present disclosure. In this embodiment, the transceiver circuit 38 includes a current processing circuit 54B, which is functionally equivalent to the current processing circuit 54 in FIG. 2.

Herein, the load LUT circuit 76 may include a current LUT (not shown) that is predetermined to correlate the time-variant input power P_{IN} (as represented by the detected time-variant amplitude \sqrt{I²+Q²} of the frequency-equalized modulation vector b_{MOD-E}^{→}) with different digital current terms. Accordingly, the load LUT circuit 76 can generate a time-variant digital current term I_{TERM} based on the detected time-variant amplitude \sqrt{I²+Q²} of the frequency equalized modulation vector b_{MOD-E}^{→}.

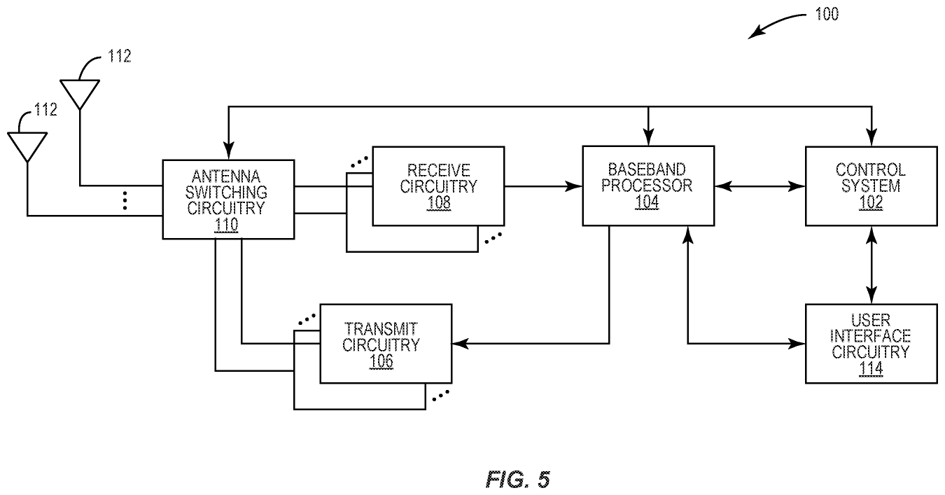

The transmission circuit 36 of FIG. 2 can be provided in a user element to enable voltage ripple cancellation according to embodiments described above. In this regard, FIG. 5 is a schematic diagram of an exemplary user element 100 wherein the transmission circuit 36 of FIG. 2 can be provided to enable voltage ripple cancellation in the transmission circuit 36 of FIG. 2.

Herein, the user element 100 can be any type of user element, such as a mobile terminal, smart watch, tablet, computer, navigation device, access point, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A transmission circuit comprising:
a power amplifier circuit configured to amplify a radio frequency (RF) signal from a time-variant input power to a time-variant output power based on a modulated voltage;
an envelope tracking (ET) integrated circuit (ETIC) coupled to the power amplifier circuit via a conductive path and configured to generate the modulated voltage based on a modulated target voltage; and
a transceiver circuit comprising:
a signal processing circuit configured to generate the RF signal in the time-variant input power based on a time-variant modulation vector;
a voltage processing circuit configured to generate a modulated digital target voltage from the time-variant modulation vector;
a current processing circuit configured to add a compensation term to the modulated digital target voltage to thereby generate a modified digital target voltage; and
a digital-to-analog converter, DAC, configured to convert the modified digital target voltage into the modulated target voltage to thereby cancel a ripple in the modulated voltage.

2. The transmission circuit of claim 1, wherein the voltage processing circuit is further configured to generate the modulated digital target voltage based on a complex voltage filter thereby to suppress an unwanted voltage distortion filter presented to the power amplifier circuit by a coupling between the power amplifier circuit and an RF front-end circuit.

3. The transmission circuit of claim 2, wherein the current processing circuit is further configured to add the compensation term to the modulated digital target voltage independent of whether the voltage processing circuit generates the modulated digital target voltage based on the complex voltage filter.

4. The transmission circuit of claim 2, wherein the current processing circuit is further configured to add the compensation term to the modulated digital target voltage concurrent to the voltage processing circuit generating the modulated digital target voltage based on the complex voltage filter.

5. The transmission circuit of claim 1, wherein:
the ripple in the modulated voltage is caused by an interaction between a modulated current in the power amplifier circuit and a total inductive impedance collectively presented to the power amplifier circuit by the ETIC and the conductive path; and
the current processing circuit is further configured to determine the compensation term in accordance with the total inductive impedance.

6. The transmission circuit of claim 5, wherein the current processing circuit comprises:
an equalizer circuit configured to apply a complex current filter to the time-variant modulation vector to generate an equalized modulation vector;
an amplitude detector configured to detect a time-variant amplitude of the equalized modulation vector;
a load lookup table, LUT, circuit configured to generate a time-variant digital current term based on the detected time-variant amplitude of the equalized modulation vector; and
a filter circuit configured to convert the time-variant digital current term into the compensation term.

7. The transmission circuit of claim 6, wherein the current processing circuit further comprises an adjustable delay circuit coupled between the load LUT circuit and the filter circuit, the adjustable delay circuit is configured to introduce an adjustable delay term into the time-variant digital current term to thereby cause the modulated current to be time aligned with the modulated voltage at the power amplifier circuit.

8. The transmission circuit of claim 7, wherein:
the voltage processing circuit comprises a second delay circuit configured to introduce a second adjustable delay term into the modulated digital target voltage; and
the signal processing circuit comprises a third delay circuit configured to introduce a third adjustable delay term into the time-variant modulation vector.

9. The transmission circuit of claim 5, wherein the voltage processing circuit comprises:
a frequency equalizer circuit configured to apply a complex voltage filter to the time-variant modulation vector to generate a frequency-equalized modulation vector; and
an amplitude detector configured to detect a time-variant amplitude of the frequency-equalized modulation vector.

10. The transmission circuit of claim 9, wherein the current processing circuit comprises:
a load lookup table, LUT, circuit configured to generate a time-variant digital current term based on the detected time-variant amplitude of the frequency-equalized modulation vector; and
a filter circuit configured to convert the time-variant digital current term into the compensation term.

11. The transmission circuit of claim 10, wherein the current processing circuit further comprises an adjustable delay circuit coupled between the load LUT circuit and the filter circuit, the adjustable delay circuit is configured to introduce an adjustable delay term into the time-variant digital current term to thereby cause the modulated current to be time aligned with the modulated voltage at the power amplifier circuit.

12. The transmission circuit of claim 11, wherein:
the voltage processing circuit comprises a second delay circuit configured to introduce a second adjustable delay term into the modulated digital target voltage; and
the signal processing circuit comprises a third delay circuit configured to introduce a third adjustable delay term into the time-variant modulation vector.

13. A transceiver circuit comprising:
a signal processing circuit configured to generate a radio frequency, RF, signal in a time-variant input power based on a time-variant modulation vector;
a voltage processing circuit configured to generate a modulated digital target voltage from the time-variant modulation vector;
a current processing circuit configured to add a compensation term to the modulated digital target voltage to thereby generate a modified digital target voltage; and
a digital-to-analog converter, DAC, configured to convert the modified digital target voltage into a modulated target voltage.

14. The transceiver circuit of claim 13, wherein the current processing circuit comprises:
an equalizer circuit configured to apply a complex current filter to the time-variant modulation vector to generate an equalized modulation vector;
an amplitude detector configured to detect a time-variant amplitude of the equalized modulation vector;
a load lookup table, LUT, circuit configured to generate a time-variant digital current term based on the detected time-variant amplitude of the equalized modulation vector; and
a filter circuit configured to convert the time-variant digital current term into the compensation term.

15. The transceiver circuit of claim 14, wherein the current processing circuit further comprises an adjustable delay circuit coupled between the load LUT circuit and the filter circuit, the adjustable delay circuit is configured to introduce an adjustable delay term into the time-variant digital current term.

16. The transceiver circuit of claim 15, wherein:
the voltage processing circuit comprises a second delay circuit configured to introduce a second adjustable delay term into the modulated digital target voltage; and
the signal processing circuit comprises a third delay circuit configured to introduce a third adjustable delay term into the time-variant modulation vector.

17. The transceiver circuit of claim 13, wherein the voltage processing circuit comprises:
a frequency equalizer circuit configured to apply a complex voltage filter to the time-variant modulation vector to generate a frequency-equalized modulation vector; and
an amplitude detector configured to detect a time-variant amplitude of the frequency-equalized modulation vector.

18. The transceiver circuit of claim 17, wherein the current processing circuit comprises:
a load lookup table, LUT, circuit configured to generate a time-variant digital current term based on the detected time-variant amplitude of the frequency-equalized modulation vector; and
a filter circuit configured to convert the time-variant digital current term into the compensation term.

19. The transceiver circuit of claim 18, wherein the current processing circuit further comprises an adjustable delay circuit coupled between the load LUT circuit and the filter circuit, the adjustable delay circuit is configured to introduce an adjustable delay term into the time-variant digital current term.

20. The transceiver circuit of claim 19, wherein:
the voltage processing circuit comprises a second delay circuit configured to introduce a second adjustable delay term into the modulated digital target voltage; and
the signal processing circuit comprises a third delay circuit configured to introduce a third adjustable delay term into the time-variant modulation vector.
